(19) United States
(12) Patent Application Publication
(10) Pub. No.: US 2012/0152347 A1
(43) Pub. Date: Jun. 21, 2012

(54) STACKED ELECTRODE AND PHOTO-ELECTRIC DEVICE HAVING THE SAME

(75) Inventors: William Lee, Taichung City (TW); Bao-Shun Yau, Kaohsiung City (TW); Chih-Chiang Lu, Taipei County (TW)

(73) Assignee: INDUSTRIAL TECHNOLOGY RESEARCH INSTITUTE, Hsinchu (TW)

(21) Appl. No.: 12/981,473

(22) Filed: Dec. 30, 2010

(30) Foreign Application Priority Data
Dec. 16, 2010 (TW) 99144311

(51) Int. Cl. H01L 31/0224

(52) U.S. Cl. 136/256

(57) ABSTRACT

A stacked electrode includes an optical match layer, a transparent conductive layer, and a metal layer. A complex refractive index of the optical match layer is N₁, and N₁=n₁−ik₁, wherein n₁ represents a refractive index of the optical match layer and k₁ represents an extinction coefficient of the optical match layer. A complex refractive index of the transparent conductive layer is N₂, and N₂=n₂−ik₂, wherein n₂ represents a refractive index of the transparent conductive layer, k₂ represents an extinction coefficient of the transparent conductive layer, n₁>n₂, and k₁<k₂. The metal layer is disposed between the optical match layer and the transparent conductive layer. A photo-electric device having the above-mentioned stacked electrode is also provided.

### CROSS-REFERENCE TO RELATED APPLICATION

This application claims the priority benefit of Taiwan application serial no. 99144311, filed on Dec. 16, 2010. The entirety of the above-mentioned patent application is hereby incorporated by reference herein and made a part of this specification.

### BACKGROUND OF THE DISCLOSURE

1. Technical Field

The disclosure is related to a photo-electric device, and in particular to a stacked electrode in a photo-electric device.

2. Description of Related Art

Since organic photovoltaic cells have advantages such as having simple structures, being easy to manufacture, and being able to reduce costs through mass production by roll-to-roll film-coating methods, organic photovoltaic cells have become the next generation and low cost products which are being actively developed by academia and the photo-electric industry. Transparent conductive electrodes with high transmittance and low resistivity are a key factor in affecting the efficiency of photovoltaic cells.

In order to increase photo-electric conversion efficiency of a photovoltaic cell, a transparent conductive electrode having high transmittance and allowing as much light as possible entering a polymer active layer of a photovoltaic cell is required. This is because the photo-electric conversion efficiency of the photovoltaic cell is positively correlated to an amount of light entering and being absorbed by the polymer active layer, and light that is reflected or absorbed by the electrode does not contribute to the photo-electric conversion efficiency. In addition, meanwhile photo-electric conversion, electrons are conducted by the transparent conductive electrode of the photovoltaic cell, and resistivity of the transparent conductive electrode significantly affects an output power of the photovoltaic cell. Therefore, the optcial and electrical characteristics of the transparent conductive electrode significantly affects the photo-electric conversion efficiency of the photovoltaic cell.

In general, the transparent conductive electrode located at a light incident side of the photovoltaic cell has characteristics of high transmittance and low resistivity. However, there is trade-off between this two characteristics (i.e. high transmittance and low resistivity). For example, if a general metal with a thickness of over 50 nm is used as the electrode, although good conductivity is obtained, the transmittance thereof is extremely low. However, if the thickness of this type of metal is reduced to several nanometers (nm) to tens of nanometers, although transmittance is slightly increased, transmittance is only increased to a limited extent due to the fact that the metal reflects light. Moreover, if a transparent conductive oxide thin film is used as the electrode, although transmittance is significantly increased (compared to a metal thin film electrode), a greater thickness or complex manufacturing processes, such as subsequent annealing treatments, are required in order to obtain low resistivity. Annealing treatments are not suitable for fabrication of the electrode on a flexible substrate (e.g. plastic substrate) because process temperature of the annealing treatments is high.

In addition to their application in photovoltaic cells, transparent conductive electrodes may also be used in organic electroluminescent devices (such as displays and lighting devices). In applications of in organic electroluminescent devices, a transparent conductive electrode may affects light-emitting efficiency in an organic electroluminescent device. Accordingly, the transparent conductive electrode in the organic electroluminescent device should have characteristics of high transmittance and low resistivity also.

During the recent decade, in order to obtain a transparent conductive electrode with high transmittance and low resistivity, oxide-metal-oxide stacked electrodes which utilize the optical interference theorem have been continuously studied. A general oxide-metal-oxide stacked electrode may adopt a symmetrical or asymmetrical stacked structure, and top and bottom oxide layers may adopt a transparent conductive oxide and a non-conductive dielectric film. However, in current studies, matching of optical qualities (i.e. refractive indexes and light absorption) of the top and bottom oxide layers has not been fully discussed.

### SUMMARY

The disclosure provides a stacked electrode and a photo-electric device having the stacked electrode.

The disclosure provides a stacked electrode which includes an optical match layer, a transparent conductive layer, and a metal layer. A complex refractive index of the optical match layer is N₁, and N₁=n₁−ik₁, wherein n₁ represents a refractive index of the optical match layer and k₁ represents an extinction coefficient of the optical match layer. A complex refractive index of the transparent conductive layer is N₂, and N₂=n₂−ik₂, wherein n₂ represents a refractive index of the transparent conductive layer, k₂ represents an extinction coefficient of the transparent conductive layer, n₁>n₂, and k₁<k₂. The metal layer is disposed between the optical match layer and the transparent conductive layer.

The disclosure also provides a photo-electric device which includes the above-described stacked electrode, an active layer, and an opposite electrode, wherein the active layer is disposed between the stacked electrode and the opposite electrode.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional diagram showing a photo-electric device according to an embodiment of the disclosure.

FIG. 2 is a diagram showing curves which represent transmittance versus wavelengths of different stacked electrodes.

In order to make the aforementioned and other objects, features and advantages of the disclosure comprehensible, embodiments accompanied with figures are described in detail below.

### DESCRIPTION OF EMBODIMENTS

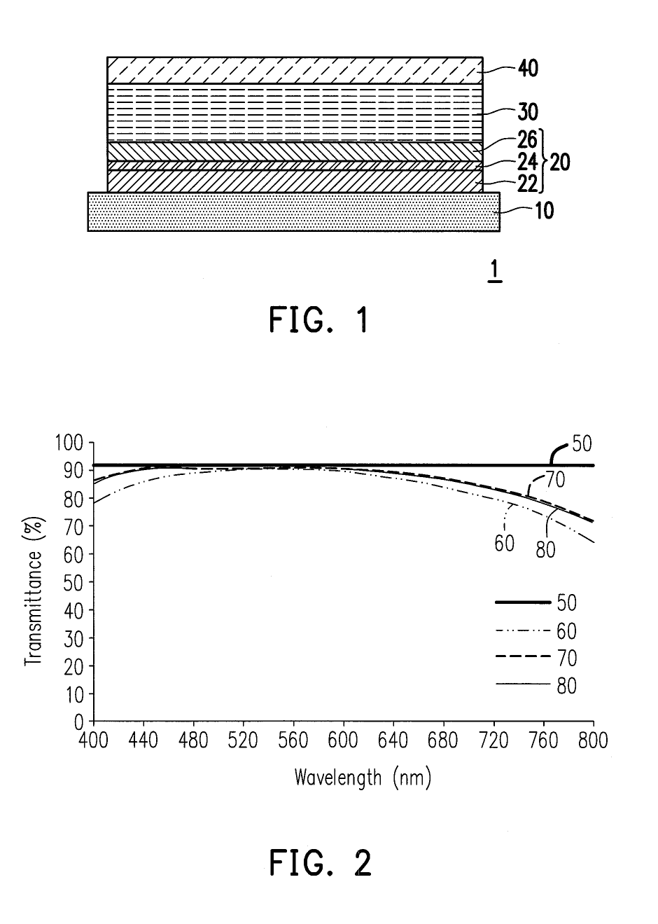

FIG. 1 is a schematic cross-sectional diagram showing a photo-electric device according to an embodiment of the disclosure. Referring to FIG. 1, a photo-electric device 1 according to the present embodiment is fabricated on a substrate 10. According to the present embodiment, the substrate 10 is, for example, a glass substrate or a soda-lime-silica float glass substrate. An optical dispersion range of the glass substrate in a wavelength range from 400 to 800 nm is, for example, from 1.50 to 1.535. According to another embodiment, the substrate 10 may also be a plastic substrate, such as a polyethylene terephthalate (PET) substrate, a polycarbonate (PC) substrate, a polyethylene naphthalate (PEN) substrate, a polyethersulfone (PES) substrate, a cyclic olefin copolymer (COC) substrate, or a polyimide (PI) substrate. An optical dispersion range of the plastic substrate in the wavelength range from 400 to 800 nm is, for example, from 1.43 to 1.67.

The photo-electric device 1 according to the present embodiment includes a stacked electrode 20, an active layer 30, and an opposite electrode 40, wherein the active layer 30 is disposed between the stacked electrode 20 and the opposite electrode 40. For example, the photo-electric device 1 is an organic electroluminescent device or a photovoltaic cell. In other words, the active layer 30 is, for example, an organic electroluminescent layer or a photo-electric conversion layer of the photovoltaic cell. It should be noted that the active layer 30 may have a single-layered structure or a multiple-layered structure. In addition, a material of the opposite electrode 40 is, for example, potassium (K), lithium (Li), sodium (Na), magnesium (Mg), lanthanum (La), cerium (Ce), calcium (Ca), strontium (Sr), barium (Ba), aluminum (Al), silver (Ag), indium (In), tin (Sn), zinc (Zn), zirconium (Zr), a silver-magnesium alloy (Ag—Mg alloy), an aluminum-lithium alloy (Al—Li alloy), an indium-magnesium alloy (In—Mg alloy), an aluminum-calcium alloy (Al—Ca alloy), a silver/magnesium stacked layer (Ag/Mg stacked layer), an aluminum/lithium stacked layer (Al/Li stacked layer), an indium/magnesium stacked layer (In/Mg stacked layer), or an aluminum/calcium stacked layer (Al/Ca stacked layer). The material of the opposite electrode 40 may also include a transparent material such as indium tin oxide (ITO), indium zinc oxide (IZO), indium cerium oxide (ICO), zinc oxide (ZnO), aluminum zinc oxide (AZO), indium zinc tin oxide IZTO), gallium zinc oxide (GZO), and tin oxide (SnO).

According to the present embodiment, the stacked electrode 20 includes an optical match layer 22, a transparent conductive layer 26, and a metal layer 24. A complex refractive index of the optical match layer 22 is N₁, and N₁=n₁−ik₁, wherein n₁ represents a refractive index (real part) of the optical match layer 22 and k₁ represents an extinction coefficient (imaginary part) of the optical match layer 22. A complex refractive index of the transparent conductive layer 26 is N₂, and N₂=n₂−ik₂, wherein n₂ represents a refractive index (real part) of the transparent conductive layer 26, k₂ represents an extinction coefficient (imaginary part) of the transparent conductive layer 26, n₁>n₂, and k₁<k₂. In general, transmittance of the stacked layer 20 is determined by the substrate and the complex refractive indexes and thicknesses of the layers stacked on the substrate. A high transmittance can only be achieved by adequately matching the complex refractive indexes and thicknesses of the thin film layers. For example, the transmittance of the optical match layer 22 and the transparent conductive layer 26 is determined by the complex refractive index N₁ of the optical match layer 22 and the complex refractive index N₂ of the transparent conductive layer 26. When light passes through the optical match layer 22 and the transparent conductive layer 26, light-absorption is determined by the extinction coefficients (imaginary part) k₁ and k₂. On the other hand, overall conductivity of the stacked electrode is determined by conductivity of each of the layers, in particular the metal layer 24. However, after the optical match layer 22 and the transparent conductive layer 26 are selected, although the addition of the metal layer 24 increases conductivity (reducing resistivity of the whole stacked electrode 20), transmittance of the stacked electrode 20 is reduced. In summary, in order that the stacked electrode 20 has characteristics of high transmittance and low resistivity in a wavelength range from 400 to 800 nm, optical characteristics and thicknesses of the optical match layer 22, the metal layer 24, and the transparent conductive layer 26 must be regulated. According to the present embodiment, n₁>n₂ and k₁<k₂, so that the stacked electrode 20 has superb transmittance for light incident on a side where the optical match layer 22 is located. Moreover, the metal layer 24 is disposed between the optical match layer 22 and the transparent conductive layer 26. According to the present embodiment, a material of the metal layer is, for example, aluminum (Al), copper (Cu), silver (Ag), platinum (Pt), gold (Au), iridium (Ir), palladium (Pd), or an alloy thereof. A thickness of the metal layer 24 is, for example, from 6 nm to 16 nm.

According to the present embodiment, a material of the optical match layer 22 is, for example, titanium oxide (TiO₂ or Ti₂O₅), zirconium oxide (ZrO₂), niobium oxide (Nb₂O₅), tungsten oxide (WOₓ), silicon nitride (Si₃N₄), indium tin oxide (ITO), indium zinc oxide (IZO), indium cerium oxide (ICO), zinc oxide (ZnO), aluminum zinc oxide (AZO), indium zinc tin oxide (IZTO), gallium zinc oxide (GZO), or tin oxide (SnO). A thickness of the optical match layer 22 is, for example, from 25 nm to 55 nm. Furthermore, a material of the transparent conductive layer 26 is, for example, a tin-doped compound, a zinc-doped compound, or an indium-doped compound. In detail, the material of the transparent conductive layer 26 is, for example, indium tin oxide (ITO), indium zinc oxide (IZO), indium cerium oxide (ICO), zinc oxide (ZnO), aluminum zinc oxide (AZO), indium zinc tin oxide (IZTO), gallium zinc oxide (GZO), or tin oxide (SnO). A thickness of the transparent conductive layer 26 is, for example, from 30 nm to 55 nm.

Generally, optical materials all have characteristics of optical dispersion. In other words, a refractive index of each optical material is not a constant but changes with a corresponding wavelength. The optical match layer 22 and the transparent conductive layer 26 according to the present embodiment are both oxides, and oxides are highly optically dispersive. Moreover, an extinction coefficient (imaginary part) of a material layer also varies with the corresponding wavelength. For example, an extinction coefficient (k value) of an indium tin oxide thin film varies as corresponding the wavelength change. In other words, the extinction coefficient of the indium tin oxide thin film corresponding to light with a wavelength near 400 nm is one to two orders greater than the extinction coefficient corresponding to light with a wavelength near 800 nm. Therefore, in the disclosure, the refractive indexes (real parts) n₁ and n₂ of the optical match layer 22 and the transparent conductive layer 26 comply with the following rules:

n₁ represents the refractive index of the optical match layer 22 corresponding to each wavelength in the wavelength range from 400 to 800 nm, and n₂ represents the refractive index of the transparent conductive layer 26 corresponding to each wavelength in the wavelength range from 400 to 800 nm, and n₁>n₂; or

n₁ represents the refractive index of the optical match layer 22 corresponding to each wavelength in the wavelength range from 400 to 450 nm, and n₂ represents the refractive index of the transparent conductive layer 26 corresponding to each wavelength in the wavelength range from 400 to 450 nm, and n₁>n₂; or

n₁ represents an average refractive index of the optical match layer 22 in the wavelength range from 400 to 800 nm, and n₂ represents an average refractive index of the transparent conductive layer 26 in the wavelength range from 400 to 800 nm, and n₁>n₂; or

n₁ represents an average refractive index of the optical match layer 22 in the wavelength range from 400 to 450 nm, and n₂ represents an average refractive index of the transparent conductive layer 26 in the wavelength range from 400 to 450 nm, and n₁>n₂.

Furthermore, in the disclosure, the extinction coefficients (imaginary parts) k₁ and k₂ of the optical match layer 22 and the transparent conductive layer 26 comply with the following rules:

k₁ represents the extinction coefficient of the optical match layer 22 corresponding to each wavelength in the wavelength range from 400 to 800 nm, and k₂ represents the extinction coefficient of the transparent conductive layer 26 corresponding to each wavelength in the wavelength range from 400 to 800 nm, and k₁<k₂; or

k₁ represents the extinction coefficient of the optical match layer 22 corresponding to each wavelength in the wavelength range from 400 to 450 nm, and k₂ represents the extinction coefficient of the transparent conductive layer 26 corresponding to each wavelength in the wavelength range from 400 to 450 nm, and k₁<k₂; or

k₁ represents an average extinction coefficient of the optical match layer 22 in the wavelength range from 400 to 800 nm, and k₂ represents an average extinction coefficient of the transparent conductive layer 26 in the wavelength range from 400 to 800 nm, and k₁<k₂; or

k₁ represents an average extinction coefficient of the optical match layer 22 in the wavelength range from 400 to 450 nm, and k₂ represents an average extinction coefficient of the transparent conductive layer 26 in the wavelength range from 400 to 450 nm, and k₁<k₂.

In summary, the stacked electrode 20 according to the present embodiment adopts an asymmetrical thin film design, meaning that the refractive index (average refractive index) and the extinction coefficient (average extinction coefficient) of the optical match layer 22 are different from the refractive index (average refractive index) and the extinction coefficient (average extinction coefficient) of the transparent conductive layer 26, so that the stacked electrode 20 has better transmittance.

### Experimental Embodiment

FIG. 2 is a diagram showing curves which represent transmittance versus wavelengths of different stacked electrodes. Referring to FIG. 2, a curve 50 represents transmittance versus wavelengths of a transparent glass BK7 substrate, a curve 60 represents transmittance versus wavelengths of a transparent glass BK7 substrate/indium tin oxide/silver/indium tin oxide, a curve 70 represents transmittance versus wavelengths of a transparent glass BK7 substrate/titanium oxide (TiO₂)/silver/indium tin oxide, and a curve 80 represents transmittance versus wavelengths of a transparent glass BK7 substrate/niobium oxide (Nb₂O₅)/silver/indium tin oxide.

The curves 50, 60, 70, and 80 are simulated under the following conditions: an incident light is vertically incident on the stacked electrode; a thickness of the transparent glass BK7 substrate is 0.5 mm, a refractive index and extinction coefficient are shown in Table 1-1 (which may represent general whiteboard glass having optical characteristics similar to certain optical grade plastic substrates, such as optical grade PET); a thickness of the silver thin film in the indium tin oxide/silver/indium tin oxide stacked electrode is 12 nn, and thicknesses of both the top and bottom indium tin oxide thin films are 37 nm, refractive indexes and extinction coefficients of the indium tin oxide thin films are shown in Table 1-2; a thickness of the titanium oxide (TiO₂) thin film in the titanium oxide (TiO₂)/silver/indium tin oxide stacked electrode is 34 nm, a refractive index and extinction coefficient of the titanium oxide (TiO₂) thin film are shown in Table 1-3; a thickness of the niobium oxide (Nb₂O₅) thin film in the niobium oxide (Nb₂O₅)/silver/indium tin oxide stacked electrode is 33.41 nm, and a refractive index and extinction coefficient of the niobium oxide (Nb₂O₅) thin film are shown in Table 1-4. The silver thin films and indium tin oxide thin films in the titanium oxide (TiO₂)/silver/indium tin oxide stacked electrode and the niobium oxide (Nb₂O₅)/silver/indium tin oxide stacked electrode have the same conditions as those in the indium tin oxide/silver/indium tin oxide stacked electrode. The data shown in Table 1-1 are quoted from configuration values in the computer simulation software TFCALC™ (produced by Software Spectra, Inc.), the data shown in Tables 1-2 and 1-3 are quoted from configuration values in the computer simulation software OPTICAL THIN FILMS™ (produced by THIN FILM CENTER, Inc.), and the data shown in Table 1-4 are calculated by performing an envelope method (described in J. Phy. E.: Sci. Inst. 9, 1002-1004) on a niobium oxide (Nb₂O₅) thin film sputtered by a sputtering coating machine (manufactured by the Japanese company Shincron, model number RAS-1100B).

TABLE 1-1
Material BK7 Glass

| Wavelength | Refractive | Extinction |
|---|---|---|
| (nm) | Index | Coefficient |
| 405 | 1.53019593 | 0 |
| 425 | 1.52782658 | 0 |
| 445 | 1.52578586 | 0 |
| 465 | 1.52401238 | 0 |
| 485 | 1.52245853 | 0 |
| 505 | 1.52108692 | 0 |
| 525 | 1.51986781 | 0 |
| 545 | 1.51877729 | 0 |
| 565 | 1.51779591 | 0 |
| 585 | 1.51690776 | 0 |
| 605 | 1.51609968 | 0 |
| 625 | 1.5153607 | 0 |
| 645 | 1.51468165 | 0 |
| 665 | 1.51405476 | 0 |
| 685 | 1.51347346 | 0 |
| 705 | 1.51293214 | 0 |
| 725 | 1.51242597 | 0 |
| 745 | 1.5119508 | 0 |
| 765 | 1.51150305 | 0 |
| 785 | 1.51107956 | 0 |
| 805 | 1.51067763 | 0 |

TABLE 1-2
Material ITO

| Wavelength | Refractive | Extinction |
|---|---|---|
| (nm) | Index | Coefficient |
| 400 | 2.182 | 0.045 |
| 450 | 2.1 | 0.021 |
| 500 | 2.06 | 0.016 |
| 550 | 2.05 | 0.014 |
| 600 | 2.04 | 0.012 |
| 650 | 2.03 | 0.011 |
| 700 | 2.02 | 0.0105 |
| 750 | 2.015 | 0.0105 |
| 800 | 1.914 | 0.01 |

TABLE 1-3
Material TiO₂

| Wavelength | Refractive | Extinction |
|---|---|---|
| (nm) | Index | Coefficient |
| 400.6 | 2.544 | 0.0025 |
| 411.3 | 2.509 | 0.002 |
| 420.4 | 2.483 | 0.0016 |
| 433 | 2.453 | 0.00131 |
| 441.1 | 2.438 | 0.00089 |
| 449.7 | 2.423 | 0.00077 |
| 465.1 | 2.399 | 0.00076 |
| 482.1 | 2.37701 | 0.00075 |
| 500.8 | 2.357 | 0.00044 |
| 521.8 | 2.338 | 0.00029 |
| 540.5 | 2.324 | 0.0002 |
| 572.5 | 2.305 | 0.00007 |
| 590.6 | 2.296 | 0 |
| 610.5 | 2.287 | 0 |
| 632.5 | 2.27901 | 0.00015 |
| 674.6 | 2.267 | 0.0003 |
| 694 | 2.263 | 0.00029 |
| 715 | 2.258 | 0.00027 |
| 800 | 2.25 | 0 |

TABLE 1-4
Material Nb₂O₅

| Wavelength | Refractive | Extinction |
|---|---|---|
| (nm) | Index | Coefficient |
| 400 | 2.47925637 | 0 |
| 420 | 2.45527249 | 0 |
| 440 | 2.43460967 | 0 |
| 460 | 2.41667874 | 0 |
| 480 | 2.40101881 | 0 |
| 500 | 2.38725954 | 0 |
| 520 | 2.37510481 | 0 |
| 540 | 2.36431452 | 0 |
| 560 | 2.35469126 | 0 |
| 580 | 2.34607123 | 0 |
| 600 | 2.3383191 | 0 |
| 620 | 2.33132296 | 0 |
| 640 | 2.32498716 | 0 |
| 660 | 2.31922927 | 0 |
| 680 | 2.3139832 | 0 |
| 700 | 2.30918784 | 0 |
| 720 | 2.30479338 | 0 |
| 740 | 2.30075706 | 0 |
| 760 | 2.29704024 | 0 |
| 780 | 2.29361034 | 0 |
| 800 | 2.29043888 | 0 |

According to the curves 60, 70, and 80 in FIG. 2, in the wavelength range of 400 nm to 800 nm, the titanium oxide (TiO₂)/silver/indium tin oxide stacked electrode and the niobium oxide (Nb₂O₅)/silver/indium tin oxide stacked electrode have high transmittance.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A stacked electrode, comprising:
an optical match layer, having a complex refractive index N₁, and N₁=n₁−ik₁, wherein n₁ represents a refractive index of the optical match layer and k₁ represents an extinction coefficient of the optical match layer;
a transparent conductive layer, having a complex refractive index N₂, and N₂=n₂−ik₂, wherein n₂ represents a refractive index of the transparent conductive layer, k₂ represents an extinction coefficient of the transparent conductive layer, n₁>n₂, and k₁<k₂; and
a metal layer, disposed between the optical match layer and the transparent conductive layer.

2. The stacked electrode as claimed in claim 1, wherein a material of the optical match layer comprises TiO₂, Ti₂O₅, ZrO₂, Nb₂O₅, WOₓ, Si₃N₄, ITO, IZO, ICO, ZnO, AZO, IZTO, GZO, or SnO.

3. The stacked electrode as claimed in claim 1, wherein a thickness of the optical match layer is from 25 nm to 55 nm.

4. The stacked electrode as claimed in claim 1, wherein a material of the transparent conductive layer comprises a tin-doped compound, a zinc-doped compound, or an indium-doped compound.

5. The stacked electrode as claimed in claim 1, wherein a material of the transparent conductive layer comprises ITO, IZO, ICO, ZnO, AZO, IZTO, GZO, or SnO.

6. The stacked electrode as claimed in claim 1, wherein a thickness of the transparent conductive layer is from 30 nm to 55 nm.

7. The stacked electrode as claimed in claim 1, wherein a material of the metal layer comprises Al, Cu, Ag, Pt, Au, Ir, or Pd.

8. The stacked electrode as claimed in claim 1, wherein a thickness of the metal layer is from 6 nm to 16 nm.

9. The stacked electrode as claimed in claim 1, wherein n₁ represents a refractive index of the optical match layer corresponding to each wavelength in a wavelength range from 400 to 800 nm, and n₂ represents a refractive index of the transparent conductive layer corresponding to each wavelength in the wavelength range from 400 to 800 nm, and n₁>n₂.

10. The stacked electrode as claimed in claim 1, wherein n₁ represents a refractive index of the optical match layer corresponding to each wavelength in a wavelength range from 400 to 450 nm, and n₂ represents a refractive index of the transparent conductive layer corresponding to each wavelength in the wavelength range from 400 to 450 nm, and n₁>n₂.

11. The stacked electrode as claimed in claim 1, wherein n₁ represents an average refractive index of the optical match layer in a wavelength range from 400 to 800 nm, and n₂ represents an average refractive index of the transparent conductive layer in the wavelength range from 400 to 800 nm.

12. The stacked electrode as claimed in claim 1, wherein n₁ represents an average refractive index of the optical match layer in a wavelength range from 400 to 450 nm, and n₂ represents an average refractive index of the transparent conductive layer in the wavelength range from 400 to 450 nm.

13. The stacked electrode as claimed in claim 1, wherein k₁ represents an extinction coefficient of the optical match layer corresponding to each wavelength in a wavelength range from 400 to 800 nm, and k₂ represents an extinction coefficient of the transparent conductive layer corresponding to each wavelength in the wavelength range from 400 to 800 nm.

14. The stacked electrode as claimed in claim 1, wherein k₁ represents an extinction coefficient of the optical match layer corresponding to each wavelength in a wavelength range from 400 to 450 nm, and k₂ represents an extinction coefficient of the transparent conductive layer corresponding to each wavelength in the wavelength range from 400 to 450 nm.

15. The stacked electrode as claimed in claim 1, wherein k₁ represents an average extinction coefficient of the optical match layer in a wavelength range from 400 to 800 nm, and k₂ represents an average extinction coefficient of the transparent conductive layer in the wavelength range from 400 to 800 nm.

16. The stacked electrode as claimed in claim 1, wherein k₁ represents an average extinction coefficient of the optical match layer in a wavelength range from 400 to 450 nm, and k₂ represents an average extinction coefficient of the transparent conductive layer in the wavelength range from 400 to 450 nm.

17. A photo-electric device, comprising:
a stacked electrode as claimed in claim 1;
an opposite electrode; and
an active layer, disposed between the stacked electrode and the opposite electrode.

18. The photo-electric device as claimed in claim 17, wherein the active layer comprises an organic electroluminescent layer or a photo-electric conversion layer of a photovoltaic cell.

19. The photo-electric device as claimed in claim 17, wherein a material of the opposite electrode comprises K, Li, Ni, Mg, La, Ce, Ca, Sr, Ba, Al, Ag, In, Sn, Zn, Zr, a Ag—Mg alloy, an Al—Li alloy, an In—Mg alloy, an Al—Ca alloy, a Ag/Mg stacked layer, an Al/Li stacked layer, an In/Mg stacked layer, an Al/Ca stacked layer, ITO, IZO, ICO, ZnO, AZO, IZTO, GZO, or SnO.
